(19) United States
(12) Patent Application Publication
(10) Pub. No.: US 2018/0096974 A1
(43) Pub. Date: Apr. 5, 2018

(54) SEMICONDUCTOR PACKAGE AND MANUFACTURING METHOD THEREOF

(71) Applicant: NANYA TECHNOLOGY CORPORATION, Taoyuan City (TW)

(72) Inventor: Po-Chun LIN, Changhua County (TW)

(21) Appl. No.: 15/281,103

(22) Filed: Sep. 30, 2016

(51) Int. Cl. H01L 25/10; H01L 23/31; H01L 23/538; H01L 25/065; H01L 25/00

(52) U.S. Cl. CPC H01L 25/105; H01L 23/3128; H01L 23/5389; H01L 23/5384; H01L 2225/1058; H01L 25/50; H01L 2225/1035; H01L 2225/107; H01L 25/0655

(57) ABSTRACT

A semiconductor package includes a semiconductor chip, an interposer, a first redistribution layer, and a molding compound. The semiconductor chip has a first surface and a second surface opposite to the first surface and at least one sidewall connected to the first surface and the second surface. The interposer is present on the first surface of the semiconductor chip. The first redistribution layer is present on the second surface of the semiconductor chip and is electrically connected to the semiconductor chip. The molding compound is present between the interposer and the first redistribution layer and is connected to the sidewall of the semiconductor chip.

### BACKGROUND

### Field of Disclosure

The present disclosure relates to a semiconductor package.

### Description of Related Art

Semiconductor devices are fabricated on a surface of a semiconductor substrate or wafer that is subsequently divided or diced into a number of chips or dies each having a device or integrated circuits IC formed thereon. One or more chips are then enclosed in a package that provides physical and chemical protection of the chip(s) while electrically connecting it with outside circuitry. The chips may be molded using molding compound. However, during manufacturing processes that apply heat to the semiconductor substrate such as, for example, solder reflow, the semiconductor substrate may warp.

### SUMMARY

An aspect of the present disclosure is to provide a semiconductor package including a semiconductor chip, an interposer, a first redistribution layer, and a molding compound. The semiconductor chip has a first surface and a second surface opposite to the first surface and at least one sidewall connected to the first surface and the second surface. The interposer is present on the first surface of the semiconductor chip. The first redistribution layer is present on the second surface of the semiconductor chip and is electrically connected to the semiconductor chip. The molding compound is present between the interposer and the first redistribution layer and is connected to the sidewall of the semiconductor chip.

In some embodiments, the semiconductor package further includes a via present in the interposer and the molding compound and electrically connected to the first redistribution layer.

In some embodiments, the semiconductor package further includes a semiconductor device electrically connected to the via. The semiconductor chip is present between the semiconductor device and the first redistribution layer.

In some embodiments, a thickness of the interposer is in a range of about 10 μm to about 1000 μm.

In some embodiments, the interposer includes Silicon, SiO₂, silicon on isolation (SOI), or combinations thereof.

In some embodiments, a Young's Modulus of the interposer is higher than a Young's Modulus of the molding compound.

In some embodiments a coefficient of thermal expansion (CTE) of the interposer is smaller than a CTE of the molding compound.

In some embodiments, the semiconductor package further includes an adhesive present between the semiconductor chip and the interposer.

In some embodiments, the semiconductor package further includes a second redistribution layer. The interposer is present between the first redistribution layer and the second redistribution layer.

Another aspect of the present disclosure is to provide a method for manufacturing a semiconductor package including disposing a semiconductor chip on a carrier. An interposer is disposed on the semiconductor chip. A molding compound is formed between the carrier and the interposer and surrounding the semiconductor chip. The carrier is removed. A first redistribution layer is formed on the semiconductor chip. The semiconductor chip is present between the interposer and the first redistribution layer.

In some embodiments, the interposer includes Silicon, SiO₂, silicon on isolation (SOI), or combinations thereof.

In some embodiments, a Young's Modulus of the interposer is higher than a Young's Modulus of the molding compound.

In some embodiments, a coefficient of thermal expansion (CTE) of the interposer is smaller than a CTE of the molding compound.

In some embodiments, the disposing the interposer on the semiconductor chip includes forming a fusion bond between the interposer and the semiconductor chip.

In some embodiments, the disposing the interposer on the semiconductor chip includes forming an adhesive on the semiconductor chip. The interposer is disposed on the adhesive.

In some embodiments, the method further includes forming a via in the molding compound and the interposer.

In some embodiments, forming the via includes forming a through hole in the molding compound and the interposer. The via is formed in the through hole.

In some embodiments, the method further includes forming a second redistribution layer on the interposer. The interposer is present between the second redistribution layer and the molding compound.

In some embodiments, the method further includes connecting a semiconductor device to the via. The semiconductor chip is present between the semiconductor device and the first redistribution layer.

In some embodiments, the method further includes forming a bump on the first redistribution layer.

### BRIEF DESCRIPTION OF THE DRAWINGS

FIGS. 1A to 1F are cross-sectional views of a method for manufacturing a semiconductor package at different stages according to some embodiments of the present disclosure;

FIG. 2 is a cross-sectional view of a semiconductor package according to some embodiments of the present disclosure;

FIG. 3 is a cross-sectional view of a semiconductor package according to some embodiments of the present disclosure; and

FIG. 4 is a cross-sectional view of a semiconductor package according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

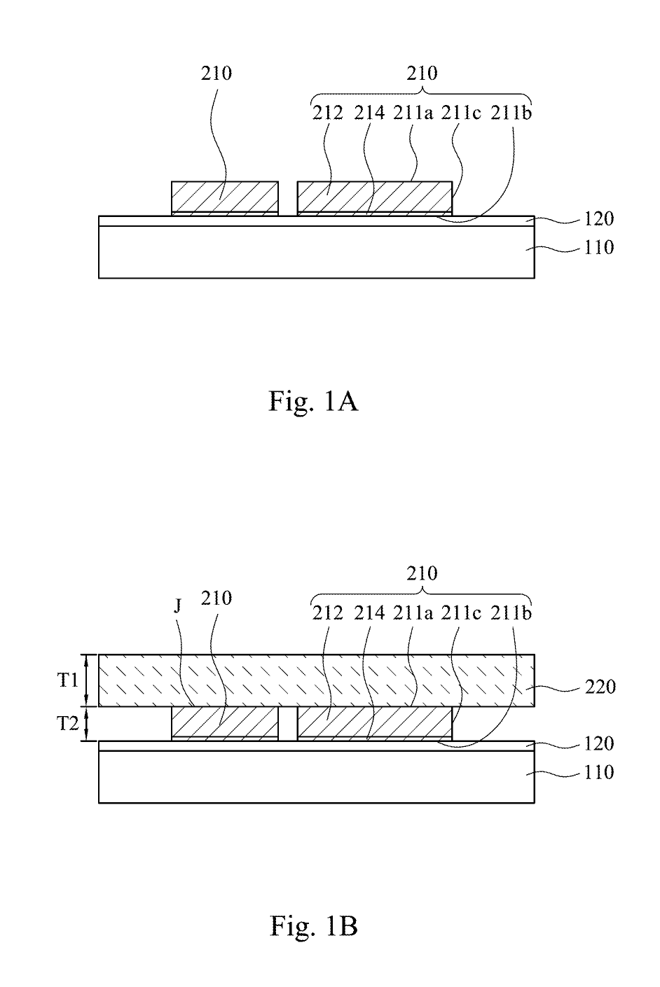

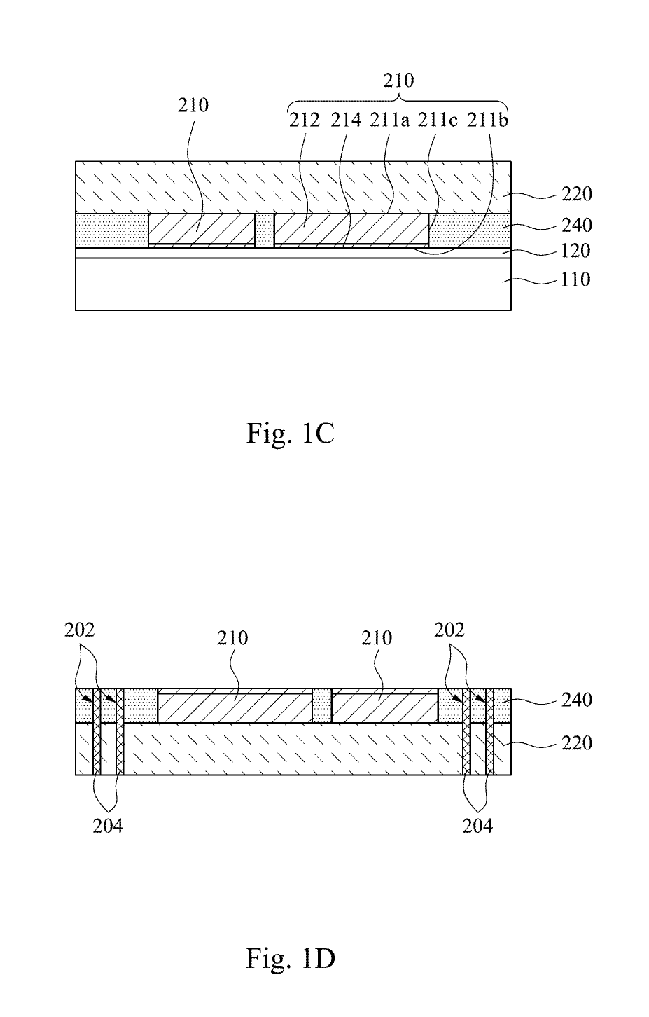

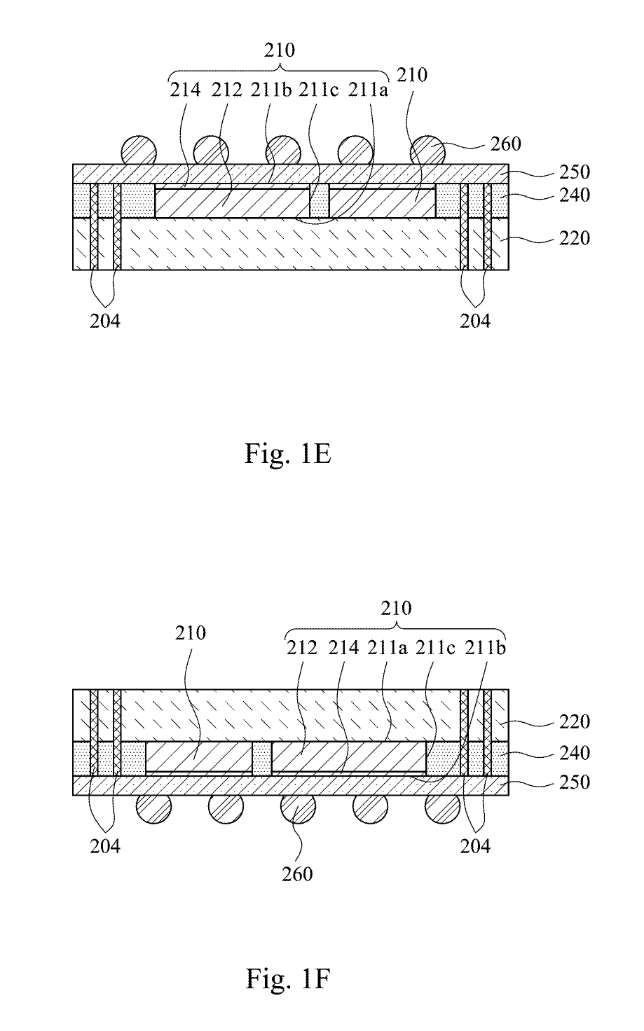

FIGS. 1A to 1F are cross-sectional views of a method for manufacturing a semiconductor package at different stages according to some embodiments of the present disclosure. Reference is made to FIG. 1A. A carrier 110 is provided. In some embodiments, the carrier 110 is made of silicon, compound semiconductors, glass, ceramics, or other suitable materials. The carrier 110 can provide sufficient stiffness for the following processing.

An adhesive 120 is formed on the carrier 110. The adhesive 120 may be a bonding film or glue. Subsequently, at least one semiconductor chip is fixed on the carrier 110. For example, in FIG. 1A, two semiconductor chips 210 are attached to the adhesive 120 to be fixed on the carrier 110. The semiconductor chips 210 may be the same or different chips. For example, one of the semiconductor chips 210 is a cache memory and another of the semiconductor chips 210 is a central processing unit (CPU) chip or a graphic processing unit (GPU) chip. In some other embodiments, the number of the semiconductor chips 210 is more than two. In some embodiments, the semiconductor chips 210 are mechanical grinded, such that the thickness of the semiconductor chips 210 is reduced.

At least one of the semiconductor chips 210 has a first surface 211a and a second surface 211b opposite to the first surface 211a and at least one sidewall 211c connected to the first surface 211a and the second surface 211b. The second surfaces 211b of the semiconductor chips 210 are attached to the adhesive 120. At least one of the semiconductor chips 210 includes a substrate 212 and an electronic layer 214 formed in or on the substrate 212. In FIG. 1A, the substrate 212 has the first surface 211a, and the electronic layer 214 has the second surface 211b.

The substrate 212 may be made of semiconductor materials, including, but not limited to, bulk silicon, a semiconductor wafer, a silicon-on-insulator (SOI) substrate, or a silicon germanium substrate. Other semiconductor materials including group III, group IV, and group V elements may also be used. The electronic layer 214 may include a plurality of microelectronic elements. Examples of the microelectronic elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.); resistors; diodes; capacitors; inductors; fuses; and other suitable elements. Various processes are performed to form the various microelectronic elements including deposition, etching, implantation, photolithography, annealing, and other suitable processes. The microelectronic elements are interconnected to form an integrated circuit, such as a logic device, memory device (e.g., SRAM), RF device, input/output (I/O) device, system-on-chip (SoC) device, combinations thereof, and other suitable types of devices.

Reference is made to FIG. 1B. An interposer 220 is disposed on the first surfaces 211a of the semiconductor chips 210, such that the semiconductor chips 210 are disposed between the interposer 220 and the carrier 110. The interposer 220 may be fusion bonded to the first surfaces 211a of the semiconductor chips 210, and joints J are formed between the interposer 220 and the semiconductor chips 210. That is, the interposer 220 is directly attached to the semiconductor chips 210. In some embodiments, the interposer 220 includes Silicon, SiO₂, SOI, or combinations thereof. The thickness T1 of the 220 can be greater than, less than, or substantially equal to the thickness T2 of the semiconductor chips 210. In some embodiments, the thickness T1 of the interposer 220 is in a range of about 10 μm to about 1000 μm. In some other embodiments, the thickness T1 of the interposer 220 is in a range of about 25 μm to about 1000 μm. In still some other embodiments, the thickness T1 of the interposer 220 is in a range of about 50 μm to about 1000 μm. The rigidity of the interposer 220 is increased when the thickness T1 of the interposer 220 is increased. In some embodiments, the total thickness of the interposer 220 and the semiconductor chips 210 (i.e., T1+T2) is about 1000 μm, and the present disclosure is not limited in this respect.

In some embodiments, a coefficient of thermal expansion (CTE) of the interposer 220 is smaller than a CTE of the molding compound 240. For example, a difference between a coefficient of thermal expansion (CTE) of the substrate 212 of the semiconductor chips 210 and a CTE of the interposer 220 is smaller than about 500 ppm/K. That is, the substrate 212 of the semiconductor chips 210 and the interposer 220 have similar or the same CTE. With such configuration, the warpage of the semiconductor package due to CTE mismatch among the elements thereof can be improved or suppressed.

In some embodiments, a seed layer (not shown) is formed on the interposer 220. The seed layer may be formed on the interposer 220 before or after the interposer 220 is fixed on the semiconductor chips 220. The seed layer can be made of metal, such as copper, copper alloy, aluminum, silver, or other suitable materials. The seed layer can provide a good adhesion between the interposer 220 and the structure formed thereon (such as a redistribution layer). The seed layer can be omitted in some embodiments.

Reference is made to FIG. 1C. A molding compound 240 is formed between the carrier 110 and the interposer 220 and surrounds the semiconductor chips 210. In other words, the molding compound 240 is connected (or attached) to the sidewalls 211c of the semiconductor chips 210. In some embodiments, the molding compound 240 fills the spaces between the interposer 220 and the carrier 110 and between the semiconductor chips 210. The molding compound 240 can be injected into the spaces to encapsulate the semiconductor chips 210. In some embodiments, the molding compound 240 can be made of epoxy resin or other suitable materials. A Young's Modulus (or elastic modulus or tensile modulus) of the interposer 220 is higher than a Young's Modulus of the molding compound 240. That is, the interposer 220 is harder to be deformed than the molding compound 240, and the warpage of the semiconductor package can be improved or suppressed.

Reference is made to FIG. 1D. The structure in FIG. 1C is flipped, and the carrier 110 and the adhesive 120 of FIG. 1C are removed. In some embodiments, the carrier 110 and the adhesive 120 are removed by chemical etching, mechanical peel-off, CMP, mechanical grinding, thermal bake, laser scanning, or wet stripping. Then, at least one through hole 202 is formed in the interposer 220 and the molding compound 240. For example, there are four through holes 202 in FIG. 1D, and the present disclosure is not limited in this respect. The through holes 202 are formed around the semiconductor chips 210. That is, the through holes 202 are spaced from the semiconductor chips 210. In some embodiments, the through holes 202 are formed by laser drilling, mechanical drilling, deep reactive ion etching, or some other suitable processes. Then, a plurality of vias 204 are respectively formed in the through holes 202. The vias 204 may be made of Al, Cu, Sn, Ni, Au, Ag, Ti, W, poly-silicon, or other suitable electrically conductive material and are formed by electrolytic plating, electroless plating process, or other suitable metal deposition process. In some embodiments, the vias 204 can be omitted.

Reference is made to FIG. 1E. A first redistribution layer 250 is formed on the second surfaces 211b of the semiconductor chips 210 and the molding compound 240, such that the first redistribution layer 250 is electrically connected to at least one of the electronic layers 214 of the semiconductor chips 210 and/or the vias 204. In some embodiments, the first redistribution layer 250 is electrically connected to at least one of the electronic layers 214 of the semiconductor chips 210 if the vias 204 are omitted. The first redistribution layer 250 may include one or more traces coupled with the vias 204 and/or the electronic layers 214 of the semiconductor chips 210 to route electrical connections therebetween. In some embodiments, the first redistribution layer 250 is formed by depositing electrically conductive materials to the second surfaces 211b of the semiconductor chips 210 and the molding compound 240 and patterning the electrically conductive materials to form traces coupled with the electronic layers 214 of the semiconductor chips 210 and the vias 204 to provide one or more input/output (I/O) signals, power, ground voltage, or combinations thereof. The deposition process can be chemical vapor deposition (CVD), physical vapor deposition (PVD), atomic layer deposition (ALD), or any other suitable deposition process. Based on the disclosure and teaching provided herein, some fabrication processes including lithography, etch, planarization, or cleaning operations may be used to form the first redistribution layer 250.

Subsequently, at least one bump 260 is formed on the first redistribution layer 250. For example, in FIG. 1E, a plurality of the bumps 260 are formed on the first redistribution layer 250. In some embodiments, the bumps 260 may be a solder bump or may be formed of a lead-free solder such as a tin-silver-copper alloy solder (i.e., Sn—Ag—Au, SAC), a tin-silver alloy solder, a tin-copper alloy solder, or other suitable materials. After the formation of the bumps 260, the structure of FIG. 1E can be flipped to be the structure of FIG. 1F.

The semiconductor package of FIG. 1F includes the semiconductor chips 210, the interposer 220, the first redistribution layer 250, the molding compound 240, and the vias 204. The interposer 220 is present on the first surfaces 211a of the semiconductor chips 210. The first redistribution layer 250 is present on the second surfaces 211b of the semiconductor chips 210 and is electrically connected to at least one of the semiconductor chips 210. The molding compound 240 is present between the interposer 220 and the first redistribution layer 250 and is connected (or attached) to the sidewalls 211c of the semiconductor chips 210. The vias 204 are present in the interposer 220 and the molding compound 240 and are electrically connected to the first redistribution layer 250.

In some embodiments, the materials of the substrates 212 of the semiconductor chips 210 and the molding compound 240 are different, which causes a CTE mismatch therebetween. The CTE mismatch may cause warpage in the semiconductor package. The warpage may interrupt or degrade electrical coupling to adjacent components such as the semiconductor chips 210, the first redistribution layer 250, and the vias 204. Furthermore, the warpage may generate cracks in the semiconductor package. In the present embodiment, however, the interposer 220 is disposed on the semiconductor chips 210 and the molding compound 240. The interposer 220 has a Young's Modulus higher than the Young's Modulus of the molding compound 240. Therefore, the interposer 220 is rigid and not easy to be deformed compared to the molding compound 240. Furthermore, since the CTE of the interposer 220 is similar to the CTE of the substrates 212 of the semiconductor chips 210, the CTE mismatch problem of the semiconductor package can be improved. With such configuration, the warpage problem of the semiconductor package can be improved or suppressed.

In FIG. 1F, the interposer 220 is electrically isolated from the semiconductor chips 210. That is, the electric signals of the semiconductor chips 210 may pass through the first redistribution layer 250, the vias 204, and the bumps 260 rather than pass through the interposer 220. The interposer 220 is also electrically isolated from the vias 204, such that the interposer 220 can be an electrical isolation between the vias 204, preventing crosstalks among the vias 204.

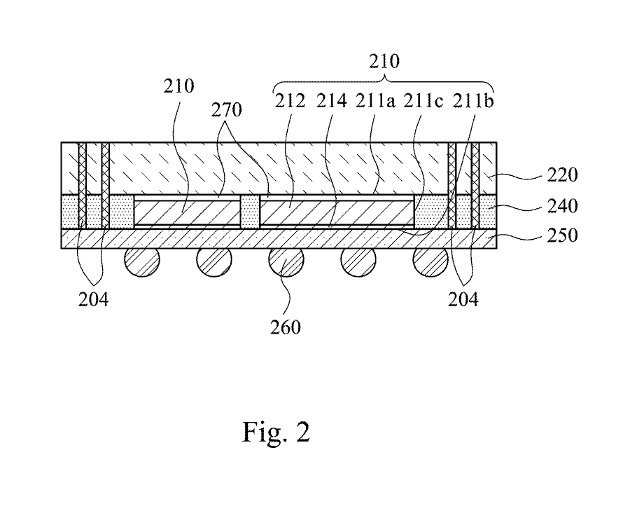

FIG. 2 is a cross-sectional view of a semiconductor package according to some embodiments of the present disclosure. The difference between the semiconductor packages of FIGS. 2 and 1F pertains to the adhered method of the semiconductor chips 210 and the interposer 220. In FIG. 2, an adhesive 270 is formed between one of the semiconductor chips 210 and the interposer 220. For example, in the process of FIG. 1B, the adhesives 270 can be respectively formed on the first surfaces 211a of the semiconductor chips 210, and the interposer 220 is then disposed on the adhesives 270, such that the interposer 220 is attached to the semiconductor chips 210 through the adhesives 270. In some embodiments, the adhesives 270 can be glue, and the present disclosure is not limited in this respect. Other relevant structural details of the semiconductor package of FIG. 2 are similar to the semiconductor package of FIG. 1F, and, therefore, a description in this regard will not be repeated hereinafter.

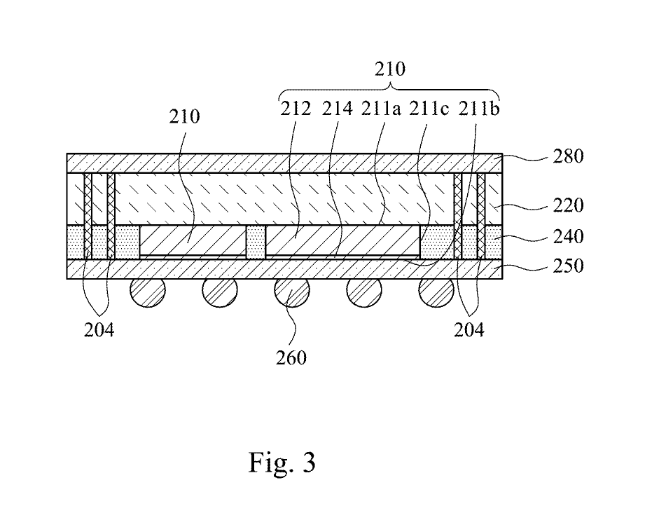

FIG. 3 is a cross-sectional view of a semiconductor package according to some embodiments of the present disclosure. The difference between the semiconductor packages of FIGS. 3 and 1F pertains to the presence of a second redistribution layer 280. In FIG. 3, a second redistribution layer 280 is formed on the interposer 220. That is, the interposer 220 is present between the first redistribution layer 250 and the second redistribution layer 280. The second redistribution layer 280 may be formed before the formation of the first redistribution layer 250 (such as in the process of FIG. 1D) or after the formation of the first redistribution layer 250 (such as in the process of FIG. 1F). The second redistribution layer 280 may include one or more traces coupled with the one or more vias 204 to route electrical connections therebetween. In some embodiments, the second redistribution layer 280 is formed by depositing electrically conductive materials to the interposer 220 and patterning the electrically conductive materials to form traces coupled with the vias 204 to provide one or more input/output (I/O) signals, power, ground voltage, or combinations thereof. The deposition process can be chemical vapor deposition (CVD), physical vapor deposition (PVD), atomic layer deposition (ALD), or any other suitable deposition process. Based on the disclosure and teaching provided herein, some fabrication processes including lithography, etch, planarization, or cleaning operations may be used to form the second redistribution layer 280. Other relevant structural details of the semiconductor package of FIG. 2 are similar to the semiconductor package of FIG. 1F, and, therefore, a description in this regard will not be repeated hereinafter.

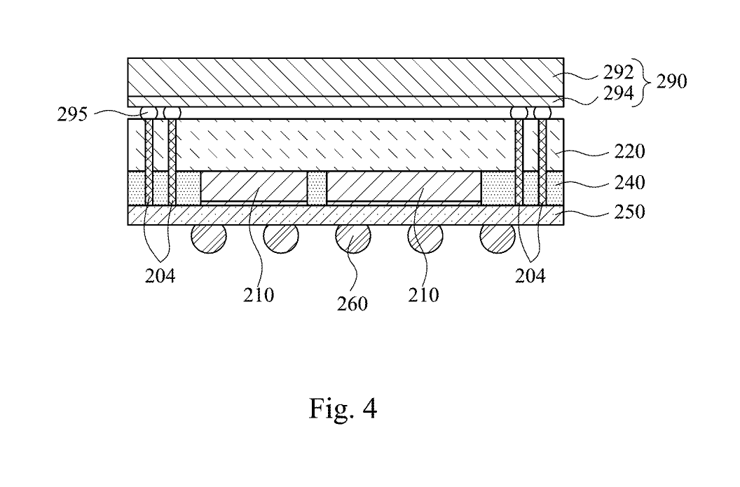

FIG. 4 is a cross-sectional view of a semiconductor package according to some embodiments of the present disclosure. The difference between the semiconductor packages of FIGS. 4 and 1F pertains to the presence of a semiconductor device. In FIG. 4, a semiconductor device 290 is bond to at least one of the vias 204, such that the semiconductor device 290 can be electrically connected to at least one of the semiconductor chips 210 through the vias 204 and the first redistribution layer 250. In FIG. 4, the semiconductor chips 210 are disposed between the semiconductor device 290 and the first redistribution layer 250. The semiconductor device 290 may be a memory device, such as a dynamic random access memory (DRAM) device, and the present disclosure is not limited in this respect. The semiconductor device 290 includes a substrate 292 and an electronic layer 294, and the electronic layer 294 faces the vias 204. The electronic layer 294 can be electrically connected to the vias 204 through connection elements 295. The connection elements 295 may be bumps or metal layers. In some embodiments, the second redistribution layer 280 of FIG. 3 can be added in the semiconductor package of FIG. 4. Other relevant structural details of the semiconductor package of FIG. 4 are similar to the semiconductor package of FIG. 1F, and, therefore, a description in this regard will not be repeated hereinafter.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

1. A semiconductor package comprising:
a semiconductor chip having a first surface and a second surface opposite to the first surface and at least one sidewall connected to the first surface and the second surface;
an interposer present on the first surface of the semiconductor chip;
a first redistribution layer present on the second surface of the semiconductor chip and electrically connected to the semiconductor chip;
a molding compound present between the interposer and the first redistribution layer and connected to the sidewall of the semiconductor chip; and
a via present in the interposer being aligned with the molding compound and not aligned with the semiconductor chip.

2. The semiconductor package of claim 1, wherein the via is further present in the molding compound, and the via is electrically connected to the first redistribution layer.

3. The semiconductor package of claim 2, further comprising a semiconductor device electrically connected to the via, wherein the semiconductor chip is present between the semiconductor device and the first redistribution layer.

4. The semiconductor package of claim 1, wherein a thickness of the interposer is in a range of about 10 μm to about 1000 μm.

5. The semiconductor package of claim 1, wherein the interposer comprises Silicon, SiO2, silicon on isolation (SOI), or combinations thereof.

6. The semiconductor package of claim 1, wherein a Young's Modulus of the interposer is higher than a Young's Modulus of the molding compound.

7. The semiconductor package of claim 1, wherein a coefficient of thermal expansion (CTE) of the interposer is smaller than a CTE of the molding compound.

8. The semiconductor package of claim 1, further comprising an adhesive present between the semiconductor chip and the interposer.

9. The semiconductor package of claim 1, further comprising a second redistribution layer, and the interposer present between the first redistribution layer and the second redistribution layer.

10-20. (canceled)

21. A semiconductor package comprising:
a semiconductor chip having a first surface and a second surface opposite to the first surface and at least one sidewall connected to the first surface and the second surface;
an interposer present on the first surface of the semiconductor chip;
a first redistribution layer present on the second surface of the semiconductor chip and electrically connected to the semiconductor chip;
a molding compound present between the interposer and the first redistribution layer and connected to the sidewall of the semiconductor chip; and
a via present in a first section of the interposer aligned with the molding compound and not present in a second section of the interposer aligned with the semiconductor chip.
